(19) United States
(12) Patent Application Publication
(10) Pub. No.: US 2012/0199462 A1
(43) Pub. Date: Aug. 9, 2012

(54) PROJECTED CAPACITIVE TOUCH PANEL WITH SENSITIVITY ADJUSTING STRUCTURE

(76) Inventor: Jane HSU, Taoyuan County (TW)

(21) Appl. No.: 13/333,347

(22) Filed: Dec. 21, 2011

(30) Foreign Application Priority Data
Feb. 8, 2011 (TW) 100202458

(51) Int. Cl. H03K 17/975

(52) U.S. Cl. 200/600

(57) ABSTRACT

A projected capacitive touch panel with sensitivity adjusting structure has an X-axis sensing layer and a Y-axis sensing layer. The X-axis sensing layer comprises multiple sensing rows and each sensing row is composed of multiple X-axis electrodes connected in series. The Y-axis sensing layer comprises multiple sensing columns, and each sensing column is composed of multiple Y-axis electrodes connected in series. The X-axis electrodes and the Y-axis electrodes are formed between each other. There is at least one hole formed on at least one X-axis electrode and at least one Y-axis electrode. The areas of the X-axis electrodes and the Y-axis electrodes decrease. Therefore, the coupling capacitance between two adjacent electrodes decreases.

### BACKGROUND OF THE INVENTION

1. Field of the Invention

The present invention relates to a projected capacitive touch panel, and more particularly to a touch panel with sensitivity adjusting structure.

2. Description of Related Art

With reference to U.S. patent publication No. 2010/0245285, a capacitive touch panel includes a transparent substrate, a plurality of first sensing electrode sets and second sensing electrode sets provided on the transparent substrate. Each first sensing electrode set includes a plurality of first sensing electrodes electrically coupled in series through a plurality of first wires. Each second sensing electrode set includes a plurality of second sensing electrodes. A color compensation layer having a mesh-like pattern is provided between the first sensing electrodes and the second sensing electrodes. The second wires cover part of the surface of the color compensation layer to couple the second sensing electrodes in series.

With reference to FIG. 11, a conventional projected capacitive touch panel comprises a substrate 70, an X-axis sensing layer 80 and a Y-axis sensing layer 90.

The substrate 70 is transparent and has a top surface and a bottom surface.

The X-axis sensing layer 80 is formed on the top surface of the substrate 70 and comprises multiple sensing rows. Each sensing row is composed of multiple X-axis electrodes 81 connected in series. The X-axis electrodes are formed in rhombic shapes. Each sensing row is electrically connected to an X-axis driving wire 82.

The Y-axis sensing layer 90 is formed on the bottom surface of the substrate 70 and is composed of multiple sensing columns. Each sensing column is composed of multiple Y-axis electrodes 91 connected in series. The Y-axis electrodes 91 are formed in rhombic shapes. Each sensing column is electrically connected to a Y-axis driving wire 92.

With reference to FIG. 12, the X-axis electrodes 81 of the X-axis sensing layer 80 and the Y-axis electrodes 91 of the Y-axis sensing layer 90 are placed between each other. Generally, the X-axis driving wires 82 of the X-axis sensing layer 80 and the Y-axis driving wires 92 of the Y-axis sensing layer 90 extend from one side to another side of the substrate 70. A connection port is mounted on one of the sides of the substrate 70, and is applied to connect to a controller. The controller will detect the capacitive changes of the X-axis sensing layer 80 and the Y-axis sensing layer 90.

In a projected capacitive touch panel, the cooperative requirement among the sensing layers and the controller is high. However, the X-axis driving wires 82 and the Y-axis driving wires 92 are along the sides of the substrate 70. In this condition, the distances between the X-axis driving wires 82 and the controller differ from the distances between the Y-axis driving wires 92 and the controller. That means that the lengths of the X-axis driving wires 82 and the Y-axis driving wires 92 are different. The impedance of each X-axis driving wire 82 or each Y-axis driving wire 92 is directly proportional to its length. The larger size of a touch panel is formed, the larger impedance of the driving wires appears. Therefore, the sensitivity and the accuracy for determining the coordinates of a touch point are affected.

With reference to FIG. 13, there are multiple X-axis electrodes 61 and multiple Y-axis electrodes 62 arranged between each other. A transparent plate 63 is mounted on the substrate 60 and covers the X-axis electrodes 61 and the Y-axis electrodes 62. If the projected capacitive touch panel is activated, a coupling capacitance Cp will be induced between one X-axis electrode 61 and one neighboring Y-axis electrode 62.

With reference to FIG. 14, if a finger or a conductor touches a surface of the transparent plate 63, a new capacitance Cf will be induced. Therefore, when a controller scans the X-axis electrodes 61 and Y-axis electrodes 62 through the multiple X-, Y-axis driving wires, the controller obtains a certain capacitance Cp+Cf to determine the coordinates of a touch point.

As a result, if the capacitance Cp between the adjacent X-axis electrode 61 and the Y-axis electrode 62 decreases, the sensitivity and the accuracy of the controller for determining the coordinates of a touch point will be promoted.

### SUMMARY OF THE INVENTION

Therefore, an objective of the present invention is to provide a projected capacitive touch panel. By reducing the size of the electrodes of the sensing layers, the coupling capacitance will decrease. The sensitivity of a touch point will be promoted.

To achieve the foregoing objective, the projected capacitive touch panel with sensitivity adjusting structure comprises an X-axis sensing layer and a Y-axis sensing layer.

The X-axis sensing layer comprises multiple sensing rows and multiple X-axis driving wires connected to the sensing rows respectively. Each sensing row comprises multiple X-axis electrodes connected in series and at least one hole formed on the X-axis electrodes.

The Y-axis sensing layer comprises multiple sensing columns and multiple Y-axis driving wires connected to the sensing columns respectively. Each sensing column comprises multiple Y-axis electrodes connected in series and at least one hole formed on the Y-axis electrodes. A capacitance is formed between each X-axis electrode and each Y-axis electrode.

To achieve the foregoing objective, the projected capacitive touch panel with sensitivity adjusting structure comprises an X-axis sensing layer and a Y-axis sensing layer.

The X-axis sensing layer comprises multiple sensing rows and multiple X-axis driving wires connected to the sensing rows respectively. Each sensing row is composed of at least two X-axis electrode strings connected in parallel. Each sensing string comprises multiple X-axis electrodes connected in series and at least one hole formed on the X-axis electrodes.

The Y-axis sensing layer comprises multiple sensing columns and multiple Y-axis driving wires connected to the sensing columns respectively. Each sensing column is composed of at least two Y-axis electrode strings connected in parallel. Each sensing string comprises multiple Y-axis electrodes connected in series and at least one hole formed on the Y-axis electrodes. A capacitance is formed between each X-axis electrode and each Y-axis electrode.

Because each X-axis electrode and each Y-axis electrodes have at least one hole respectively, the areas over which the electrode material is distributed decrease. The coupling capacitance between two adjacent X-axis electrodes and Y-axis electrodes is directly proportional to the areas of the X-axis electrodes and the Y-axis electrodes. If the areas of the X-axis electrodes and the Y-axis electrodes decrease, the coupling capacitances will be lower. Therefore, when a finger or a conductor approaches the touch panel and generates a new capacitance, under the condition that an original capacitance value of the coupling capacitance is small, the sensitivity for the variation of the capacitance is raised.

Therefore, the sensitivity of the touch panel is promoted. In addition, even though the impedance of driving wires of a large size touch panel is large, the sensitivity is not lowered. Because the sensitivity of the touch panel is promoted via the art in accordance with this invention, the sensitivity issue in large size touch panels is resolved.

### BRIEF DESCRIPTION OF THE DRAWINGS

FIG. 1 is a cross-sectional view of a first embodiment in accordance with the present invention;

FIG. 2 is an exploded perspective view of a second embodiment in accordance with the present invention;

FIG. 3 is a plan view of an X-axis sensing layer and a Y-axis sensing layer of the projected capacitive touch panel in FIG. 2;

FIG. 4 is a plan view of an X-axis sensing layer and a Y-axis sensing layer of a third embodiment in accordance with the present invention;

FIG. 5 is a plan view of an X-axis sensing layer and a Y-axis sensing layer of a fourth embodiment in accordance with the present invention;

FIG. 6 is a plan view of an X-axis sensing layer and a Y-axis sensing layer of a fifth embodiment in accordance with the present invention;

FIG. 7 is a plan view of an X-axis sensing layer and a Y-axis sensing layer of a sixth embodiment in accordance with the present invention;

FIG. 8 is a cross-sectional view of a seventh embodiment in accordance with the present invention;

FIG. 9 is an exploded perspective view of an eighth embodiment in accordance with the present invention;

FIG. 10 is a plan view of an X-axis sensing layer and a Y-axis sensing layer of the projected capacitive touch panel in FIG. 9;

FIG. 11 is an exploded perspective view of a conventional projected capacitive touch panel;

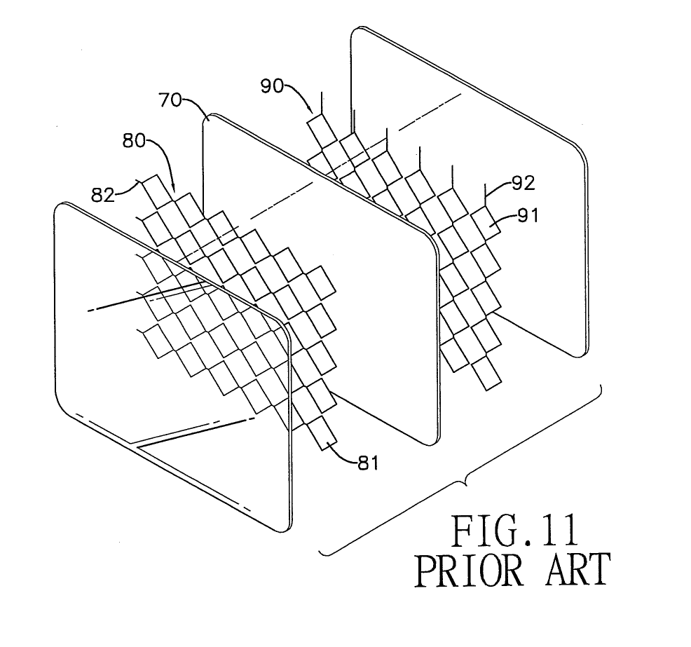

FIG. 12 is a plan view of a conventional projected capacitive touch panel;

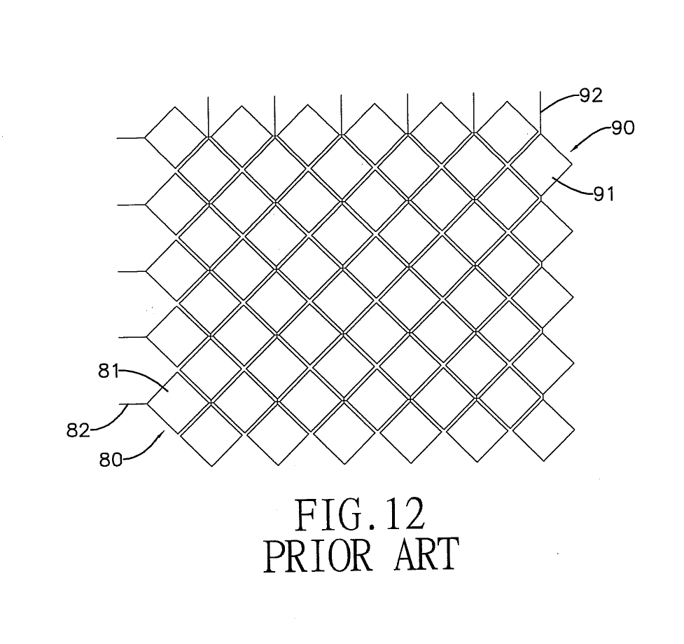

FIG. 13 is an illustration that coupling capacitances Cp are formed between two adjacent X-axis electrodes and two adjacent Y-axis electrodes;

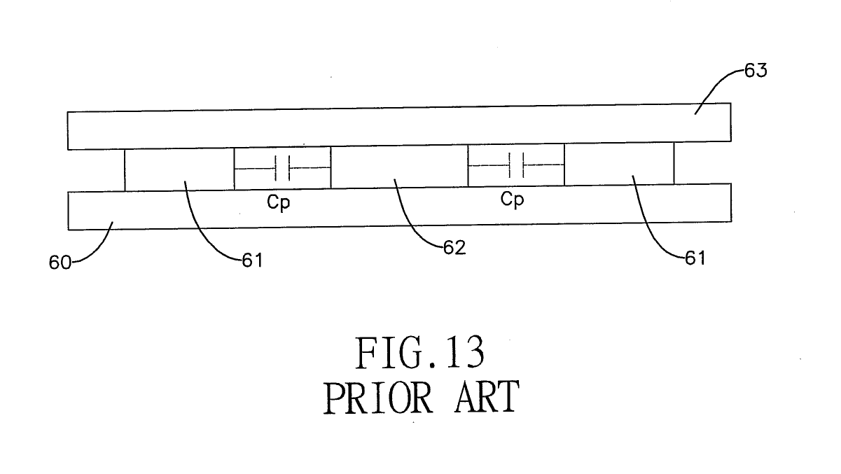

FIG. 14 is an illustration of capacitances Cp+Cf.

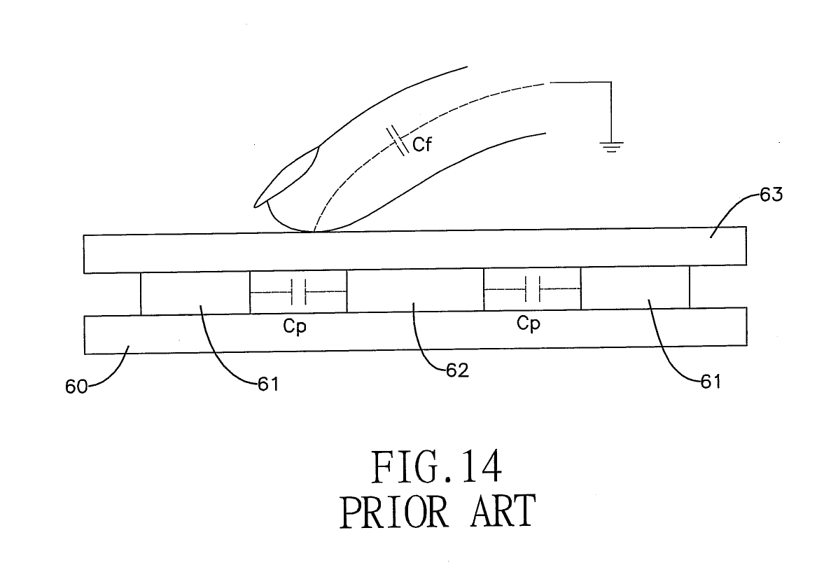

### DETAILED DESCRIPTION OF THE PREFERRED EMBODIMENT

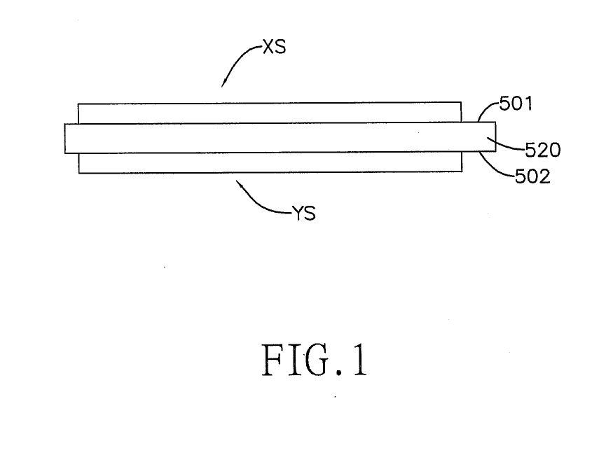

With reference to FIG. 1, a first embodiment in accordance with the present invention comprises an X-axis sensing layer XS and a Y-axis sensing layer YS. The X-axis sensing layer XS and the Y-axis sensing layer YS may be formed on a top surface 501 and a bottom surface 502 of a substrate 500 respectively.

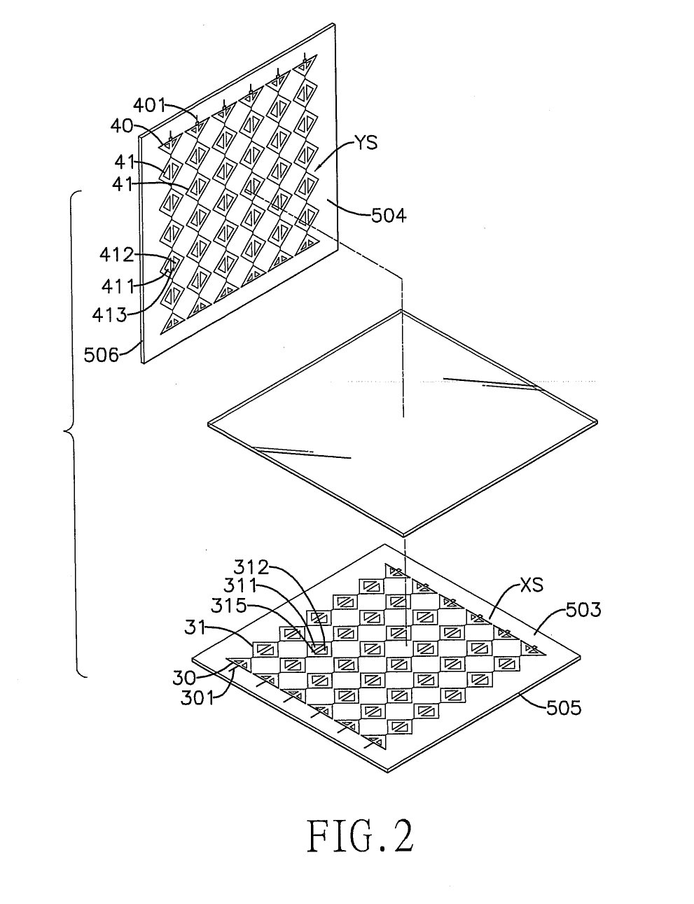

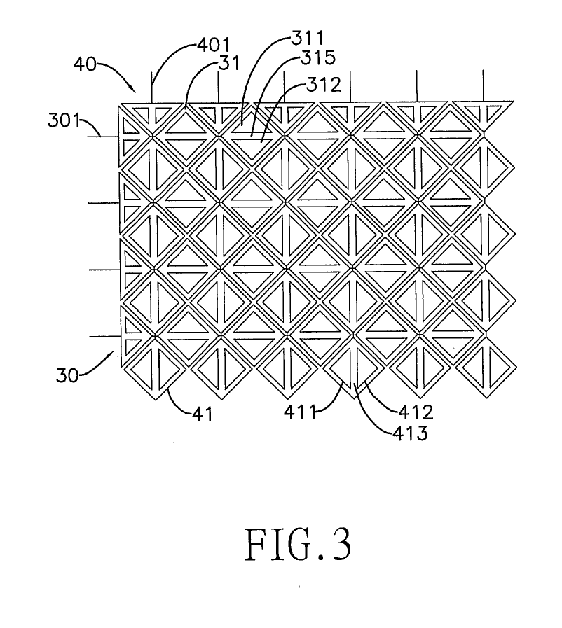

With reference to FIG. 2 and FIG. 3, a second embodiment in accordance with the present invention is disclosed. The X-axis sensing layer XS and the Y-axis sensing layer YS may be formed on two opposite surfaces 503, 504 of two substrates 505, 506 respectively. A connection port is mounted on the substrates 505, 506.

The X-axis sensing layer XS comprises multiple sensing rows 30. Each sensing row 30 has one terminal electrically connected to an X-axis driving wire 301 formed on the substrate 505. Each sensing row 30 is composed of multiple X-axis electrodes 31 connected in series.

At least one hole 311, 312 is formed on each X-axis electrode 31. In the embodiment, there are two holes 311, 312 formed on each X-axis electrode 31. The two holes 311, 312 in each X-axis electrode 31 are formed in triangular shapes and opposite to each other, which means a base-side of one hole 311 is opposite to a base-side of the other hole 312. A passage 315 is formed between the two holes 311, 312, and the passages 315 in the same sensing row 30 are located in a line to form a continuous signal path.

The Y-axis sensing layer YS comprises multiple sensing columns 40. Each sensing column 40 has one terminal electrically connected to a Y-axis driving wire 401 formed on the substrate 506. Each sensing column 40 is composed of multiple Y-axis electrodes 41 connected in series.

At least one hole 411, 412 is formed on each Y-axis electrode 41. Similarly, there are two holes 411, 412 formed on each Y-axis electrode 41. In this embodiment, the two holes 411, 412 are formed in triangular shapes and opposite to each other, which means a base-side of one hole 411 is opposite to a base-side of the other hole 412. A passage 413 is formed between the two holes 411, 412, and the passages 413 in the same sensing column 40 are located in a line to form a continuous signal path.

Because there are holes 311, 312, 411, 412 formed on the X-axis electrodes 31 and the Y-axis electrodes 41, the areas where the electrode material is distributed over the substrates 505, 506 are reduced. Therefore, the coupling capacitances between two adjacent X-axis electrodes 31 and two adjacent Y-axis electrodes 41 decrease.

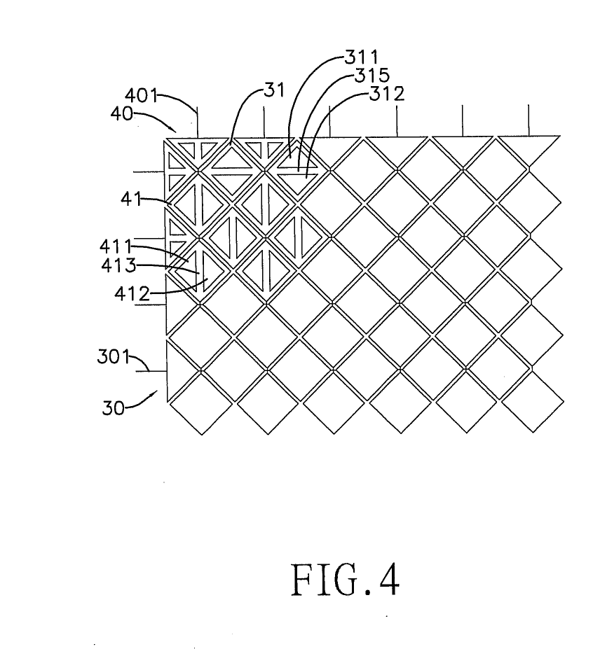

In the second embodiment described above, the holes 311, 312, 411, 412 are formed on all the X-axis electrodes 31 and all the Y-axis electrodes 41 respectively. With reference to FIG. 4, a third embodiment in accordance with the present invention is disclosed. The holes 311, 312, 411, 412 are only formed on some of the X-axis electrodes 31 and some of the Y-axis electrodes 41 located at a certain position on the substrate. Said certain position is far from the connection port on the substrates.

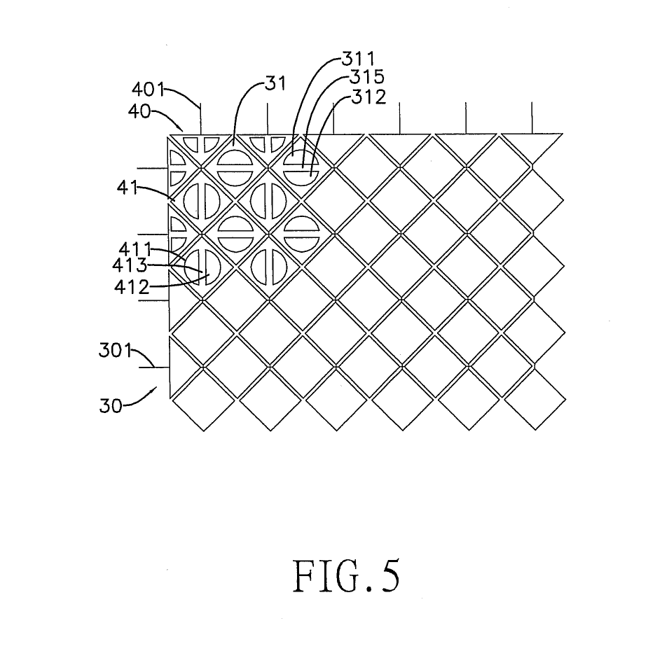

With reference to FIG. 5, a fourth embodiment in accordance with the present invention is disclosed. The difference between the fourth embodiment and the embodiments described above is that the two holes 311, 312, 411, 412 are formed in semicircular shapes and opposite to each other, which means a base-side of one hole 311, 411 is opposite to a base-side of the other hole 312, 412. The passages 315, 413 are formed between two holes 311, 312, and 411, 412 respectively.

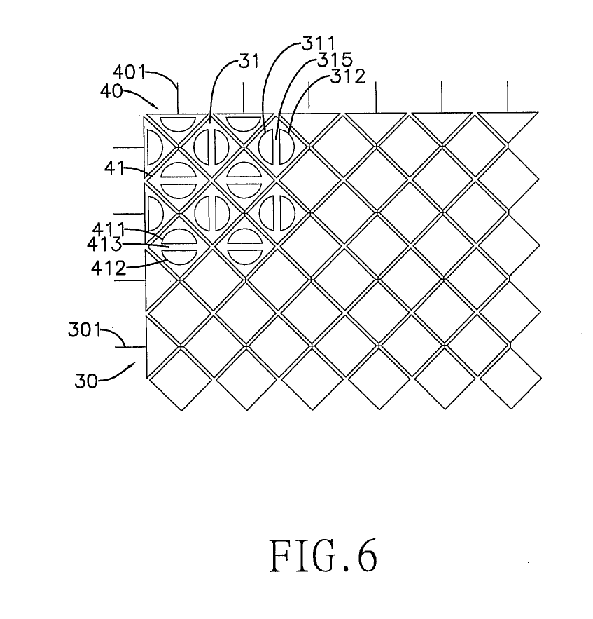

With reference to FIG. 6, a fifth embodiment in accordance with the present invention is disclosed. The difference between the fifth embodiment and the fourth embodiment is that the passages 315 in two adjacent X-axis electrodes 31 of one sensing row 30 are parallel to each other, and the passages 413 in two adjacent Y-axis electrodes 41 of one sensing column 40 are parallel to each other.

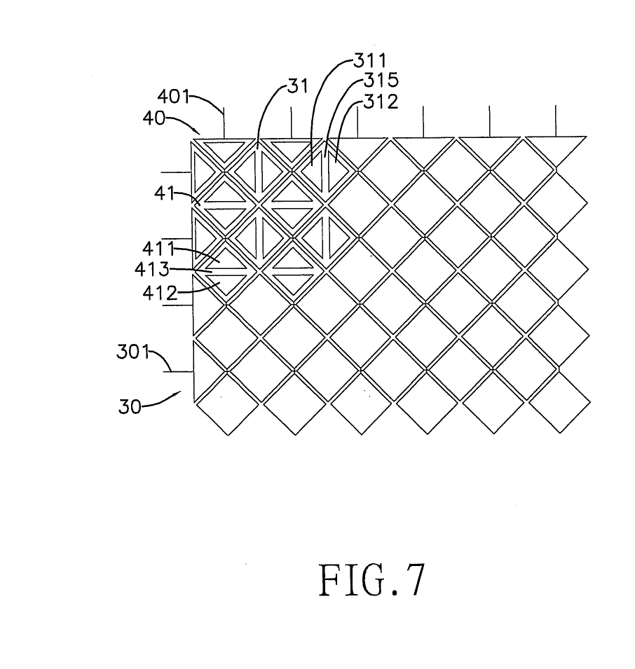

With reference to FIG. 7, a sixth embodiment in accordance with the present invention is disclosed. The difference between the sixth embodiment and the third embodiment is that the passages 315 in two adjacent X-axis electrodes 31 of one sensing row 30 are parallel to each other, and the passages 413 in two adjacent Y-axis electrodes 41 of one sensing column 40 are parallel to each other.

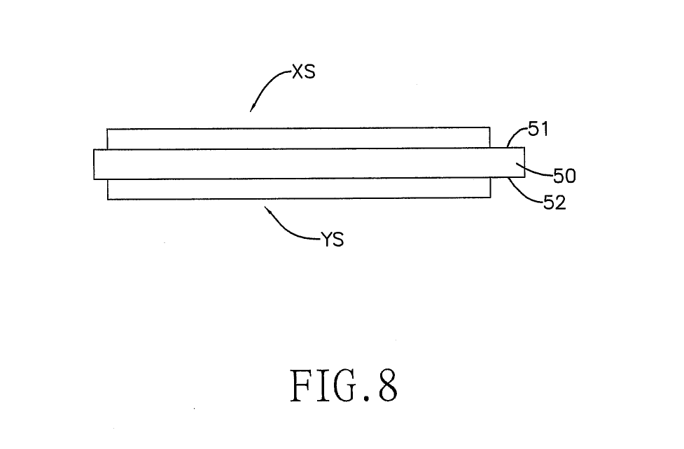

With reference to FIG. 8, a seventh embodiment in accordance with the present invention is disclosed. The seventh embodiment mainly comprises an X-axis sensing layer XS and a Y-axis sensing layer YS respectively formed on a top surface 51 and a bottom surface 52 of a substrate 50.

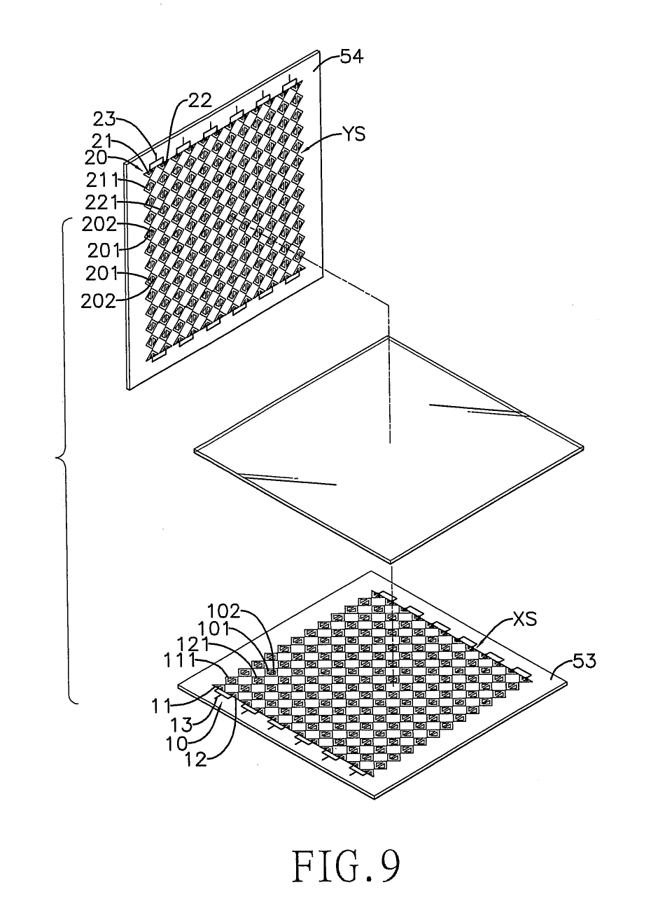

With reference to FIG. 9, the X-axis sensing layer XS and the Y-axis sensing layer YS of an eighth embodiment are respectively formed on two opposite surfaces of two substrates 53, 54.

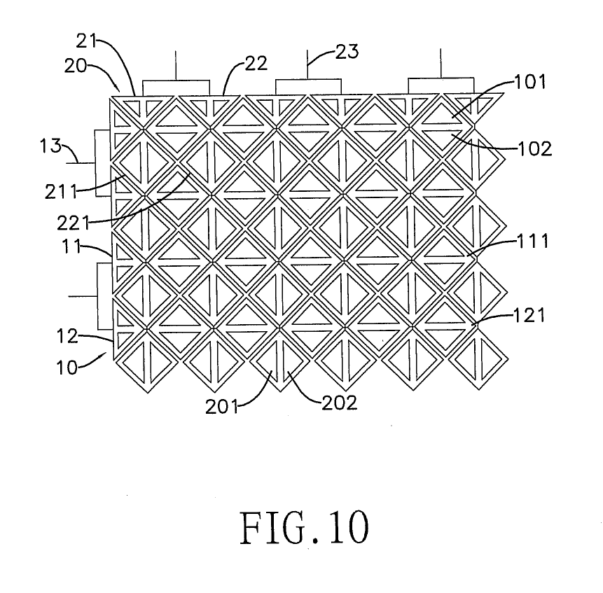

With reference to FIG. 10, the X-axis sensing layer comprises multiple sensing rows 10. Each sensing row 10 has a terminal electrically connected to an X-axis driving wire 13. Each sensing row 10 is composed of at least two X-axis electrode strings 11, 12 connected in parallel. In this embodiment, each sensing row 10 is composed of two X-axis electrode strings 11, 12 connected in parallel. Each X-axis electrode string 11, 12 is composed of multiple X-axis electrodes 111, 121 connected in series. There are two holes 101, 102 formed on each X-axis electrode 111, 121 as the embodiments described above.

The Y-axis sensing layer YS comprises multiple sensing columns 20. Each sensing column 20 has a terminal electrically connected to a Y-axis driving wire 23. Each sensing column 20 is composed of at least two Y-axis electrode strings 21, 22 connected in parallel. Each Y-axis electrode string 21, 22 is composed of multiple Y-axis electrodes 211, 221 connected in series. There are two holes 201, 202 formed on each Y-axis electrode 211, 221 as the embodiments described above.

Because the X-axis electrode strings 11, 12 are made of transparent electrodes, such as ITO, there exists impedance. In this embodiment, the X-axis electrode strings 11, 12 of each sensing row 10 are connected in parallel. Therefore, the equivalent impedance of the parallel X-axis electrode strings is smaller than the impedance of a single X-axis electrode string. In other words, when the X-axis electrode strings 11, 12 are connected in parallel, the impedance of the sensing row 10 decreases. Similarly, the Y-axis electrode strings 21, 22 of each sensing column 20 are connected in parallel, too. The impedance of the sensing columns 20 decreases. Because the holes 101, 102, 201, 202 are formed on the X-axis electrodes 111,121 and the Y-axis electrodes 211,221 respectively, the coupling capacitance decreases. Hence, the sensitivity of the touch panel in accordance with the present invention is promoted.

Moreover, the holes 101, 102, 201, 202 are formed on some X-axis electrodes 111, 121 and some Y-axis electrodes 211, 212 located at a certain position on the substrates. Said certain position is far from the connection port on the substrates. The holes 101, 102, 201, 202 may be formed in triangular shapes, semicircular shapes or other geometric patterns.

What is claimed is:

1. A projected capacitive touch panel with sensitivity adjusting structure comprising:
an X-axis sensing layer comprising
multiple sensing rows, each sensing row comprising
multiple X-axis electrodes connected in series; and
at least one hole formed on the X-axis electrodes; and
multiple X-axis driving wires connected to the sensing rows respectively; and
a Y-axis sensing layer comprising
multiple sensing columns, each sensing column comprising
multiple Y-axis electrodes connected in series, wherein a capacitance is formed between each X-axis electrode and each Y-axis electrode; and
at least one hole formed on the Y-axis electrodes; and
multiple Y-axis driving wires connected to the sensing columns respectively.

2. The projected capacitive touch panel with sensitivity adjusting structure as claimed in claim 1, wherein
there are two holes formed on at least one X-axis electrode respectively; and
there are two holes formed on at least one Y-axis electrode respectively.

3. The projected capacitive touch panel with sensitivity adjusting structure as claimed in claim 2, wherein
the X-axis electrodes and the Y-axis electrodes are formed in rhombic shapes;
a passage is formed between the two holes of each X-axis electrode, and the passages in the same sensing row are arranged in a line; and
a passage is formed between the two holes of each Y-axis electrode, and the passages in the same sensing column are located in a line.

4. The projected capacitive touch panel with sensitivity adjusting structure as claimed in claim 3, wherein the two holes in each X-axis electrode and each Y-axis electrode are formed in triangular shapes and opposite to each other.

5. The projected capacitive touch panel with sensitivity adjusting structure as claimed in claim 3, wherein the two holes in each X-axis electrode and each Y-axis electrode are formed in semicircular shapes and opposite to each other.

6. The projected capacitive touch panel with sensitivity adjusting structure as claimed in claim 2, wherein
the X-axis electrodes and the Y-axis electrodes are formed in rhombic shapes;
a passage is formed between two holes of each X-axis electrode, and the passages in two adjacent X-axis electrodes of one sensing row are parallel to each other; and
a passage is formed between two holes of each Y-axis electrode, and the passages in two adjacent Y-axis electrodes of one sensing column are parallel to each other.

7. The projected capacitive touch panel with sensitivity adjusting structure as claimed in claim 6, wherein the two holes in each X-axis electrode and each Y-axis electrode are formed in triangular shapes and opposite to each other.

8. The projected capacitive touch panel with sensitivity adjusting structure as claimed in claim 6, wherein the two holes in each X-axis electrode and each Y-axis electrode are formed in semicircular shapes and opposite to each other.

9. A projected capacitive touch panel with sensitivity adjusting structure comprising
an X-axis sensing layer comprising
multiple sensing rows, each sensing row composed of at least two X-axis electrode strings connected in parallel, each sensing string comprising
multiple X-axis electrodes connected in series; and
at least one hole formed on the X-axis electrodes; and
multiple X-axis driving wires connected to the sensing rows respectively; and
a Y-axis sensing layer comprising
multiple sensing columns, each sensing column composed of at least two Y-axis electrode strings connected in parallel, each sensing string comprising
multiple Y-axis electrodes connected in series, wherein a capacitance is formed between each X-axis electrode and each Y-axis electrode; and
at least one hole formed on the Y-axis electrodes; and
multiple Y-axis driving wires connected to the sensing columns respectively.

10. The projected capacitive touch panel with sensitivity adjusting structure as claimed in claim 9, wherein
there are two holes formed on at least one X-axis electrode respectively; and
there are two holes formed on at least one Y-axis electrode respectively.

11. The projected capacitive touch panel with sensitivity adjusting structure as claimed in claim 10, wherein
the X-axis electrodes and the Y-axis electrodes are formed in rhombic shapes;
a passage is formed between two holes of each X-axis electrode, and the passages in the same sensing row are located in a line; and
a passage is formed between two holes of each Y-axis electrode, and the passages in the same sensing column are located in a line.

12. The projected capacitive touch panel with sensitivity adjusting structure as claimed in claim 11, wherein the two holes in each X-axis electrode and each Y-axis electrode are formed in triangular shapes and opposite to each other.

13. The projected capacitive touch panel with sensitivity adjusting structure as claimed in claim 11, wherein the two holes in each X-axis electrode and each Y-axis electrode are formed in semicircular shapes and opposite to each other.

14. The projected capacitive touch panel with sensitivity adjusting structure as claimed in claim 10, wherein
the X-axis electrodes and the Y-axis electrodes are formed in rhombic shapes;
a passage is formed between two holes of each X-axis electrode, and the passages in two adjacent X-axis electrodes of one sensing row are parallel to each other; and
a passage is formed between two holes of each Y-axis electrode, and the passages in two adjacent Y-axis electrodes of one sensing column are parallel to each other.

15. The projected capacitive touch panel with sensitivity adjusting structure as claimed in claim 14, wherein the two holes in each X-axis electrode and each Y-axis electrode are formed in triangular shapes and opposite to each other.

16. The projected capacitive touch panel with sensitivity adjusting structure as claimed in claim 14, wherein the two holes in each X-axis electrode and each Y-axis electrode are formed in semicircular shapes and opposite to each other.
